(19) United States
(12) Patent Application Publication
(10) Pub. No.: US 2025/0333877 A1
(43) Pub. Date: Oct. 30, 2025

(54) AlN SINGLE CRYSTAL SUBSTRATE AND DEVICE

(71) Applicant: NGK INSULATORS, LTD., Nagoya-shi (JP)

(72) Inventors: Eri KAWAGUCHI, Nagoya-shi (JP); Kyohei ATSUJI, Nagoya-shi (JP); Katsuyuki TAKEUCHI, Aisai-shi (JP); Hiroharu KOBAYASHI, Kasugai-shi (JP)

(21) Appl. No.: 19/256,242

(22) Filed: Jul. 1, 2025

Related U.S. Application Data
(63) Continuation of application No. PCT/JP2023/000869, filed on Jan. 13, 2023.

(51) Int. Cl. C30B 29/40; C01B 21/072; H10H 20/825

(52) U.S. Cl. CPC C30B 29/403; C01B 21/072; H10H 20/8252; C01P 2002/84; C01P 2006/80

(57) ABSTRACT

An AlN single crystal substrate containing carbon and boron as impurities is provided, in which a ratio of a boron concentration to a carbon concentration is 0.22≤[boron concentration]/[carbon concentration]≤6.85 when the carbon concentration and the boron concentration are expressed in terms of the number of atoms per 1 cm³. By adjusting the concentration of impurities, an AlN single crystal substrate that can achieve a high transmittance in the ultraviolet region; and the like are provided.

### CROSS-REFERENCE TO RELATED APPLICATION

This application is a continuation application of International Patent Application No. PCT/JP2023/000869 filed on Jan. 13, 2023, the entire contents of which are incorporated herein by reference.

### TECHNICAL FIELD

The present invention relates to an AlN single crystal substrate and a device. In particular, the present invention relates to an AlN single crystal substrate used for manufacturing a light emitting diode (LED) that emits light in the ultraviolet region; and the like.

### BACKGROUND ART

In recent years, there has been a demand for LEDs that emit light in the ultraviolet region. As such a LED, a LED that emits light in the deep ultraviolet region can be utilized for sterilization and other purposes. As the base substrate thereof, an AlN single crystal substrate is used.

PTL 1 discloses that by substituting some of the Al atoms of AlN crystal with group IIIa elements (Sc, Y, La, and the like) and/or group IIIb elements (B, Ga, In, and the like) and substituting one adjacent nitrogen (N) atom with an oxygen (O) atom, a shallow impurity level is formed and low-resistance n-type AlN crystal can be obtained. In particular, PLT 1 discloses that the total concentration (C_{3A}) of group IIIa elements and/or group IIIb elements is equal to or larger than 1×10¹⁸ cm⁻³ and the O concentration (C_{O}) is 0.01C_{3A}<C_{O}<1.5C_{3A}. Moreover, PLT 1 discloses that methods such as a CVD method, an MBE method, and a sublimation method can be adopted as methods for producing AlN crystal.

PTL 2 discloses an aluminum nitride single crystal containing an oxygen atom and a carbon atom, in which the requirement in formula [O]—[C]>0 is satisfied when the concentration of oxygen atoms is denoted as [O] cm⁻³ and the concentration of carbon atoms is denoted as [C] cm⁻³.

### CITATION LIST

### Patent Literature

PTL 1: Japanese Patent Application Publication No. 2007-261883
PTL 2: Japanese Patent Application Publication No. 2012-188344

### SUMMARY OF INVENTION

### Technical Problem

In a case where an AlN single crystal substrate is used as an LED that emits light in the ultraviolet region, the AlN single crystal substrate is required to have a high transmittance in the ultraviolet region. In order to obtain an AlN single crystal substrate having a high transmittance in the ultraviolet region, it is only required to, for example, decrease the concentration of impurities contained in the AlN single crystal substrate.

However, in order to obtain an AlN single crystal substrate having a low impurity concentration, advanced control during single crystal growth and a special manufacturing apparatus are necessary to decrease the impurity concentration. Such a manufacturing apparatus is generally expensive, and this increases the manufacturing cost of an AlN single crystal substrate. Therefore, there is room for improvement in the method for controlling the impurity concentration in order to obtain an AlN single crystal substrate having a high transmittance in the ultraviolet region.

An object of the present invention is to provide an AlN single crystal substrate that can achieve a high transmittance in the ultraviolet region by adjusting the concentration of impurities; and the like.

### Solution to Problem

In order to solve the above problems, the present invention provides an AlN single crystal substrate containing carbon and boron as impurities, in which a ratio of a boron concentration to a carbon concentration is 0.22≤[boron concentration]/[carbon concentration]≤6.85 when the carbon concentration and the boron concentration are expressed in terms of the number of atoms per 1 cm³.

The present invention also provides an AlN single crystal substrate containing carbon and boron as impurities, in which a carbon concentration and a boron concentration are set so that an absorption coefficient for ultraviolet light having a wavelength of 265 nm is less than 60/cm.

The present invention further provides a device including the above AlN single crystal substrate.

### Advantageous Effects of Invention

By adjusting the concentration of impurities, it is possible to provide an AlN single crystal substrate that can achieve a high transmittance in the ultraviolet region; and the like.

### BRIEF DESCRIPTION OF DRAWINGS

FIG. 1 is a view illustrating an apparatus used for heat treatment of AlN polycrystalline powder.

FIG. 2 is a view illustrating a deposition apparatus used to deposit an AlN single crystal layer.

### DESCRIPTION OF EMBODIMENTS

Hereinafter, embodiments of the present invention will be described in detail with reference to the accompanying drawings.

### <AlN Single Crystal Substrate>

In the present embodiment, the “AlN single crystal substrate” refers to a substrate formed of a single crystal of aluminum nitride (AlN). Here, the “single crystal” does not mean that the entire substrate is formed of single crystal, and the substrate may include, for example, crystal defects.

The AlN single crystal substrate of the present embodiment contains carbon (C) and boron (B) as impurities. The ratio of the boron concentration to the carbon concentration is 0.22≤[boron concentration]/[carbon concentration]≤6.85 when the carbon concentration and the boron concentration are expressed in terms of the number of atoms per 1 cm³. It is not preferable that [boron concentration]/[carbon concentration] is less than 0.22 since the amount of C impurity, which is considered to have absorption in the deep ultraviolet region, becomes relatively large. It is not preferable that [boron concentration]/[carbon concentration] exceeds 6.85 since extremely small pores are likely to be generated and light is scattered.

From the viewpoint of transmittance in the ultraviolet region, this ratio is preferably 1.17≤[boron concentration]/[carbon concentration]≤5.09. This ratio is still more preferably 1.45≤[boron concentration]/[carbon concentration]≤3.33.

Furthermore, silicon (Si) may be contained as an impurity. In this case, the ratio of the silicon concentration to the carbon concentration may be 0.005≤[silicon concentration]/[carbon concentration]≤0.27 when the silicon concentration is expressed in terms of the number of atoms per 1 cm³.

This ratio is preferably 0.01≤[silicon concentration]/[carbon concentration]≤0.2. This ratio is still more preferably 0.02 [silicon concentration]/[carbon concentration]≤0.08.

By selecting such elements as the impurities contained in the AlN single crystal substrate and setting the concentrations of the elements to the above ratios, the transmittance of the AlN single crystal substrate in the ultraviolet region can be improved. In other words, the transmittance of the AlN single crystal substrate in the ultraviolet region can be improved when impurities are contained as well. The transmittance of the AlN single crystal substrate in the ultraviolet region can be improved without using advanced control during single crystal growth of the AlN single crystal substrate and a special manufacturing apparatus. As a result, the manufacturing cost of the AlN single crystal substrate is likely to be low.

From the viewpoint of comparison with the conventional technology, in a case where the carbon concentration is more than 4×10¹⁷ to 3×10¹⁸ cm⁻³ as well, it is possible to obtain an AlN single crystal having a high transmittance in the ultraviolet region (for example, 265 nm) by controlling the carbon concentration and the boron concentration in the above ranges.

In the present embodiment, the absorption coefficient for ultraviolet light having a wavelength of 265 nm is required to be less than 60/cm. The absorption coefficient is still more preferably less than 50/cm. The absorption coefficient can be measured by the following method.

The total light transmittance Ta of the AlN single crystal is measured using a spectrophotometer. The absorption coefficient α of AlN single crystal is determined by the following Formula (I) using this measured value and the theoretical transmittance Tt of AlN single crystal, and then the transmittance T100 μm converted to 100 μm is calculated by the following Formula (II). Here, t is the actual thickness (cm) of the sample.

α=−ln(Ta/Tt)/t (I)

T100μm=exp(−α/100) (II)

The carbon concentration, the boron concentration, and the silicon concentration are preferably in the ranges of the following Formulas (1) to (3).

3.7×10¹⁸ cm⁻³≤[carbon concentration]≤5.0×10¹⁹ cm⁻³ (1)

9.4×10¹⁸ cm⁻³≤[boron concentration]≤8.4×10¹⁹ cm⁻³ (2)

1.0×10¹⁷ cm⁻³≤[silicon concentration]≤2.0×10¹⁹ cm⁻³ (3)

The carbon concentration, the boron concentration, and the silicon concentration are still more preferably in the ranges of the following Formulas (4) to (6).

6.5×10¹⁸ cm⁻³≤[carbon concentration]≤1.3×10¹⁹ cm⁻³ (4)

1.3×10¹⁹ cm⁻³≤[boron concentration]≤2.3×10¹⁹ cm⁻³ (5)

2.0×10¹⁷ cm⁻³≤[silicon concentration]≤4.9×10¹⁸ cm⁻³ (6)

By setting the carbon concentration, the boron concentration, and the silicon concentration in the ranges of Formulas (1) to (3), the absorption coefficient of the AlN single crystal substrate in the ultraviolet region is likely to be small.

The AlN single crystal substrate in the present embodiment is preferably an oriented layer oriented in both the c-axis direction and the a-axis direction, and may include a mosaic crystal. The mosaic crystal refers to an assembly of crystals, which do not have clear grain boundaries but has the orientation that is slightly different from either or both of the c-axis and a-axis. Such an oriented layer has a configuration in which the crystal orientation is generally aligned approximately in the normal direction (c-axis direction) and the in-plane direction (a-axis direction). By adopting such a configuration, it is possible to form a semiconductor layer, which is excellent in quality, particularly excellent in orientation, thereon. In other words, when a semiconductor layer is formed on the oriented layer, the crystal orientation of the semiconductor layer generally follows the crystal orientation of the oriented layer. Therefore, the semiconductor film formed on the AlN single crystal substrate is likely to be an oriented film.

### <Method for Manufacturing AlN Single Crystal Substrate>

The AlN single crystal substrate of the present embodiment can be manufactured by various methods. A seed substrate may be prepared and epitaxial deposition may be performed thereon, or an AlN single crystal substrate may be directly manufactured by spontaneous nucleation without using a seed substrate. As the seed substrate used, an AlN substrate may be used to achieve homoepitaxial growth, or a substrate other than this may be used to achieve heteroepitaxial growth. For the growth of single crystal, any of a vapor phase deposition method, a liquid phase deposition method, or a solid phase deposition method may be used, but preferably, the AlN single crystal is deposited by a vapor phase deposition method, and then the seed substrate portion is ground and removed if necessary to obtain the desired AlN single crystal substrate. Examples of the vapor deposition method include various chemical vapor deposition (CVD) methods (for example, thermal CVD method, plasma CVD method, and MOVPE method), sputtering method, a hydride vapor phase epitaxy (HVPE) method, a molecular beam epitaxy (MBE) method, a sublimation method, and a pulsed laser deposition (PLD) method, and a sublimation method or an HVPE method is preferable. Examples of the liquid phase deposition method include a solution growth method (for example, a flux method). It is also possible to obtain an AlN single crystal substrate by a step of forming an oriented precursor layer, a step of converting the oriented precursor layer into an AlN single crystal layer by heat treatment, and a step of grinding and removing the seed substrate without directly depositing an AlN single crystal on a seed substrate. Examples of the method for depositing the oriented precursor layer at that time include an aerosol deposition (AD) method and a hypersonic plasma particle deposition (HPPD) method.

### <Device>

A device can also be fabricated using the AlN single crystal substrate of the present embodiment. In other words, a device including an AlN single crystal substrate is preferably provided. Examples of such a device include deep ultraviolet laser diodes, deep ultraviolet diodes, power electronic devices, radio frequency devices, and heat sinks. The method for manufacturing a device using an AlN single crystal substrate is not particularly limited, and the device can be manufactured by a known method.

### EXAMPLES

### <Fabrication of AlN Single Crystal Substrate>

AlN single crystal substrates having the compositions presented in Table 1 below were fabricated. In other words, AlN single crystal substrates were fabricated so that the concentrations (C amount, B amount, and Si amount) of carbon (C), boron (B), and silicon (Si), which were impurities, were the concentrations presented in Table 1, respectively. At this time, [silicon concentration]/[carbon concentration] (Si/C) and [boron concentration]/[carbon concentration] (B/C) are as presented in Table 1. The concentrations (C amount, B amount, and Si amount) are rounded off to one decimal place and written. In this regard, at the concentrations (C amount, B amount, and Si amount) written in Table 1, Si/C and B/C are not the values written in Table 1 in some cases, but Si/C and B/C calculated based on accurate concentrations taking the second or higher decimal place into consideration are written in Table 1.

TABLE 1

| | C | B | Si | | | |
|---|---|---|---|---|---|---|
| | amount/ | amount/ | amount/ | | | Absorption |
| | cm³ | cm³ | cm³ | Si/C | B/C | coefficient |
| Example 1 | 8.0E+18 | 1.4E+19 | <1.0E+17 | 0.00 | 1.77 | A |
| Example 2 | 1.2E+19 | 1.8E+19 | 4.2E+17 | 0.03 | 1.46 | A |
| Example 3 | 6.6E+18 | 2.2E+19 | 4.8E+17 | 0.07 | 3.32 | A |
| Example 4 | 8.2E+18 | 1.6E+19 | 3.3E+17 | 0.04 | 2.01 | A |
| Example 5 | 6.6E+18 | 1.6E+19 | 3.3E+17 | 0.05 | 2.48 | A |
| Example 6 | 1.1E+19 | 1.6E+19 | 2.1E+17 | 0.02 | 1.44 | B |
| Example 7 | 1.2E+19 | 1.6E+19 | 3.3E+17 | 0.03 | 1.36 | B |
| Example 8 | 1.2E+19 | 1.4E+19 | 1.5E+17 | 0.01 | 1.18 | B |
| Example 9 | 3.7E+18 | 1.4E+19 | 1.0E+18 | 0.27 | 3.65 | B |
| Comparative | 4.5E+19 | 9.3E+18 | 4.4E+17 | 0.01 | 0.21 | C |
| Example 1 | | | | | | |
| Comparative | 1.6E+20 | 1.2E+17 | 4.4E+19 | 0.28 | 0.00 | C |
| Example 2 | | | | | | |
| Comparative | 1.2E+19 | 8.5E+19 | 3.4E+17 | 0.03 | 6.86 | C |
| Example 3 | | | | | | |

### Example 1

In Example 1, an AlN single crystal substrate was fabricated by a sublimation method. The sublimation method used in Example 1 includes steps of (a) heat treatment of AlN polycrystalline powder and (b) deposition of an AlN single crystal layer.

### (a) Heat Treatment of AlN Polycrystalline Powder

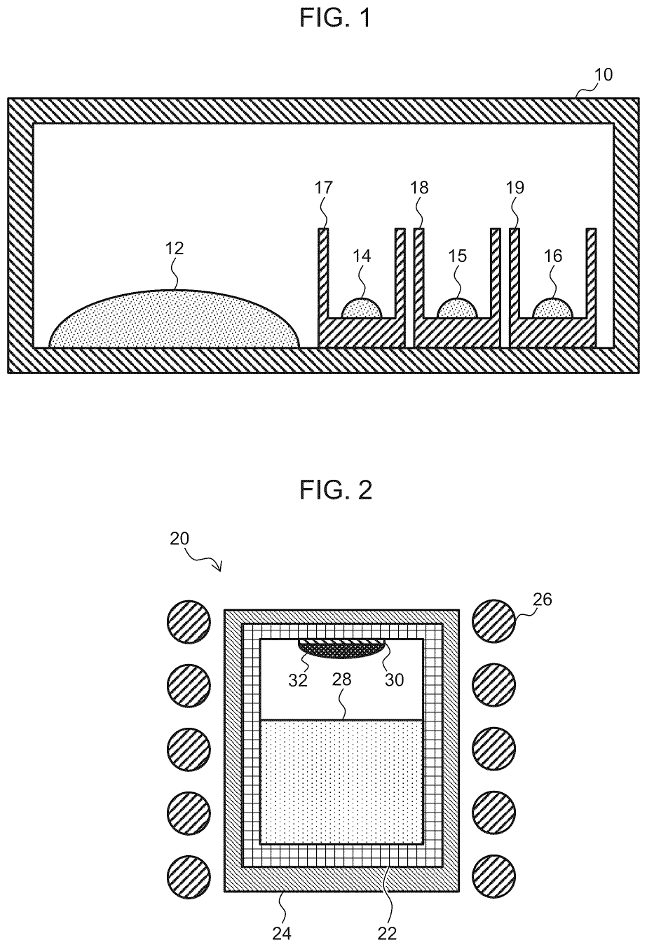

FIG. 1 is a view illustrating an apparatus used for heat treatment of AlN polycrystalline powder.

In a BN sheath 10, a commercially available AlN powder 12 having an average particle size of 1 μm, which was used as a raw material for AlN single crystal, was disposed. Commercially available graphite powder 14 having an average particle size of 1 μm was placed in a BN crucible 17 at a proportion to be 6 parts by weight with respect to 100 parts by weight of AlN powder. BN powder 15 having an average particle size of 3 μm was placed in a BN crucible 18 at a proportion to be 3 parts by weight with respect to 100 parts by weight of AlN powder. Furthermore, Si₃N₄ powder 16 having an average particle size of 0.1 μm was placed in a BN crucible 19 at a proportion to be 1 part by weight with respect to 100 parts by weight of AlN powder. These BN crucibles 17 to 19 were disposed in the BN sheath 10 so as not to directly come into contact with the AlN powder 12. The BN crucibles 17 to 19 have a size that can be stored within the BN sheath 10. This BN sheath 10 was subjected to heat treatment in a graphite heater furnace in an N₂ atmosphere at 0.1 atm to 10 atm and 2200° C. In this manner, heat treatment of the AlN powder 12, which was AlN polycrystalline powder, was performed to fabricate AlN raw material powder.

### (b) Deposition of AlN Single Crystal Layer

FIG. 2 is a view illustrating a deposition apparatus 20 used to deposit an AlN single crystal layer.

The illustrated deposition apparatus 20 includes a heat insulating material 24 for insulating a crucible 22, which is a crystal growth container, and a coil 26 for heating the crucible 22.

Then, the crucible 22 containing the AlN raw material powder 28 fabricated in (a) above was disposed inside the deposition apparatus 20. Furthermore, a SiC substrate was disposed in the upper portion of the deposition apparatus 20 so as not to come into contact with the crucible 22, as a seed substrate 30 on which a sublimate of the AlN raw material powder 28 was precipitated.

Next, the crucible 22 was pressurized at 50 kPa in an N₂ atmosphere, and a portion of the crucible 22 near the AlN raw material powder was heated to 100° C. by high frequency induction heating using the coil 26. Meanwhile, a portion of the crucible 22 near the SiC substrate was heated to a temperature lower than the temperature (temperature difference of 200° C.) and maintained at that temperature, thereby reprecipitating an AlN single crystal layer 32 on the SiC substrate. The maintained time was 10 hours.

As a result, it was possible to fabricate an AlN single crystal substrate in which the concentrations (C amount, B amount, and Si amount) of carbon (C), boron (B), and silicon (Si) had the compositions presented in Table 1, respectively. The concentration of each element was measured using a dynamic secondary ion mass spectrometry (SIMS) as a measuring apparatus. Specifically, the measuring apparatus was CAMECA IMS-7f manufactured by AMETEK Inc., and the primary ion species was Cs⁺, the primary acceleration voltage was 15 kV, and the detection area was 20 μm×20 μm. The lower measurement limits of carbon (C), boron (B), and silicon (Si) by this measuring apparatus are all 1.0×10¹⁷ cm⁻³.

### Examples 2 to 9 and Comparative Examples 1 to 3

AlN single crystal substrates were fabricated in the same manner as in Example 1, except that the amounts of the graphite powder 14, the BN powder 15, and the Si₃N₄ powder 16 were changed. As a result, it was possible to fabricate AlN single crystal substrates in which the concentrations (C amount, B amount, and Si amount) of carbon (C), boron (B), and silicon (Si) had the compositions presented in Table 1, respectively.

### <Evaluation Method>

For the AlN single crystal substrates fabricated in Examples 1 to 9 and Comparative Examples 1 to 3, the absorption coefficient was calculated by the above-mentioned Formulas (I) and (II). At this time, as the spectrophotometer for measuring the total light transmittance Ta, UH4150 manufactured by Hitachi High-Tech Science Corporation was used.

The evaluation criteria for absorption coefficient were set as follows.
Grade A: Absorption coefficient in ultraviolet region (265 nm) is less than 50/cm
Grade B: Absorption coefficient in ultraviolet region (265 nm) is equal to or larger than 50/cm and less than 60/cm
Grade C: Absorption coefficient in ultraviolet region (265 nm) is equal to or larger than 60/cm

In the case of grade B, the result of absorption coefficient is favorable. In the case of grade A, the result of absorption coefficient is still more favorable. On the other hand, in the case of grade C, the result of absorption coefficient is poor.

### <Evaluation Results>

The evaluation results are presented in Table 1.

Examples 1 to 9 are cases where carbon (C) and boron (B) are contained as impurities and the ratio (B/C) of the boron concentration to the carbon concentration is 0.22≤[boron concentration]/[carbon concentration]≤6.85. Examples 2 to 9 are cases where silicon (Si) is further contained as an impurity and the ratio (Si/C) of the silicon concentration to the carbon concentration is 0.005≤[silicon concentration]/[carbon concentration]≤0.27. In Example 1, silicon (Si) as an impurity is equal to or smaller than the detection limit, and the calculated Si/C is 0.005 but is presented here as 0.00.

In Examples 1 to 9, the absorption coefficient was grade A or grade B and was favorable.

Comparative Example 1 is a case where carbon (C) and boron (B) are contained as impurities but the ratio (B/C) of the boron concentration to the carbon concentration is less than 0.22.

Comparative Example 2 is a case where boron (B) is hardly contained as an impurity. The calculated B/C is 0.001 but is presented here as 0.00.

Comparative Example 3 is a case where carbon (C) and boron (B) are contained as impurities but the ratio (B/C) of the boron concentration to the carbon concentration exceeds 6.85.

In Comparative Examples 1 to 3, the absorption coefficient was grade C and was poor.

The present embodiment has been described above, but the technical scope of the present invention is not limited to the scope described in the above embodiment. It is apparent from the description of claims that those obtained by adding various modifications and improvements to the above embodiment are also included in the technical scope of the present invention.

### REFERENCE SIGNS LIST

12 AlN powder
14 Graphite powder
15 BN powder
16 Si₃N₄ powder
17, 18, and 19 BN crucible
20 Deposition apparatus
28 AlN raw material powder

1. An AlN single crystal substrate comprising carbon and boron as impurities, wherein
a ratio of a boron concentration to a carbon concentration is 0.22≤[boron concentration]/[carbon concentration]≤6.85 when the carbon concentration and the boron concentration are expressed in terms of a number of atoms per 1 cm³.

2. The AlN single crystal substrate according to claim 1, wherein the ratio of the boron concentration to the carbon concentration is 1.17≤[boron concentration]/[carbon concentration]≤5.09.

3. The AlN single crystal substrate according to claim 1, further comprising silicon as an impurity, wherein
a ratio of a silicon concentration to a carbon concentration is 0.005≤[silicon concentration]/[carbon concentration]≤0.27 when the silicon concentration is expressed in terms of a number of atoms per 1 cm³.

4. The AlN single crystal substrate according to claim 3, wherein the ratio of the silicon concentration to the carbon concentration is 0.01≤[silicon concentration]/[carbon concentration]≤0.2.

5. The AlN single crystal substrate according to claim 3,
wherein the carbon concentration, the boron concentration, and the silicon concentration are in ranges of Formulas (1) to (3) below:
3.7×10¹⁸ cm⁻³≤[carbon concentration]≤5.0×10¹⁹ cm⁻³ (1)
9.4×10¹⁸ cm⁻³≤[boron concentration]≤8.4×10¹⁹ cm⁻³ (2)
1.0×10¹⁷ cm⁻³≤[silicon concentration]≤2.0×10¹⁹ cm⁻³ (3).

6. An AlN single crystal substrate comprising carbon and boron as impurities, wherein a carbon concentration and a boron concentration are set so that an absorption coefficient for ultraviolet light having a wavelength of 265 nm is less than 60/cm.

7. The AlN single crystal substrate according to claim 6, further comprising silicon as an impurity, wherein
the carbon concentration, the boron concentration, and the silicon concentration are set so that the absorption coefficient for ultraviolet light having the wavelength of 265 nm is less than 60/cm.

8. A device comprising the AlN single crystal substrate according to claim 1.
